(19) United States
(12) Patent Application Publication
(10) Pub. No.: US 2018/0335449 A1
(43) Pub. Date: Nov. 22, 2018

(54) PROBE CARD

(71) Applicant: MPI CORPORATION, CHU-PEI CITY (TW)

(72) Inventors: Keng-Sheng CHANG, CHU-PEI CITY (TW); Chen-Kang CHIU, CHU-PEI CITY (TW)

(21) Appl. No.: 15/970,077

(22) Filed: May 3, 2018

(30) Foreign Application Priority Data
May 16, 2017 (TW) 106206932

(51) Int. Cl. G01R 1/073; G01R 1/04

(52) U.S. Cl. CPC G01R 1/07342; G01R 1/0491; G01R 1/0416

(57) ABSTRACT

A probe card including a substrate, a plurality of probe heads and a wave absorber is provided. The substrate has a through hole. The plurality of probe heads are disposed on the substrate and arranged around the through hole. Each of the probe heads includes a housing, a subminiature connector and a probe structure. The subminiature connector is disposed on the housing. The probe structure is connected to the subminiature connector, inserted through the housing and extended to the through hole. The wave absorber is disposed between two of the probe structures.

### BACKGROUND OF THE INVENTION

### 1. Field of the Invention

The present invention relates to a probe card and more particularly, to a probe card applied to test an integrated circuit.

### 2. Description of the Related Art

During the test process of the integrated circuit, a tester transmits test signals to the integrated circuit through a probe card contacting the integrated circuit, thereby examining the integrated circuit to find out whether the function thereof conforms to the expectancy. The probe card usually includes a plurality of dimensionally precise probes. During the test process of the integrated circuit, the probes contact mini-sized contacts, such as pads or bumps, of a device under test (hereinafter referred to as “DUT”) for transmitting the test signals from the tester and cooperating with the control process of the probe card and the tester to attain the objective of testing the integrated circuit. With the development of smaller and smaller intervals between the contacts of the DUT, the probe manufactured by the microelectromechanical system manufacturing process (hereinafter referred to as “MEMS manufacturing process”) for the fine pitch application is more and more popular.

In another aspect, in the high-frequency field, it is more and more demanding to reduce the interference and crosstalk among the signals between the integrated circuit and the probes. However, the conventional probe cards are usually unable to reduce the interference and crosstalk among the signals between the integrated circuit and the probes effectively. Therefore, the test result of the integrated circuit is usually influenced by the interference and crosstalk.

### SUMMARY OF THE INVENTION

The present invention provides a probe card capable of reducing the interference and crosstalk between the signals in adjacent probes when performing a multi-DUT testing.

The probe card of the present invention includes a substrate, a plurality of probe heads, and a wave absorber. The substrate has a through hole. The plurality of probe heads are disposed on the substrate and arranged around the through hole. Each of the probe heads includes a housing, a subminiature connector, and a probe structure. The subminiature connector is disposed on the housing. The probe structure is connected to the subminiature connector, inserted through the housing and extended to the through hole. The wave absorber is disposed between two of the probe structures.

As a result, the probe card of the present invention includes a plurality of probe heads, and a wave absorber is disposed between the probe structures of two of the probe heads for segregating and restraining the electromagnetic wave of the probe structures, thereby reducing the interference and crosstalk between the signals of the two probe structures. In this way, when the probe card is applied to test a plurality of DUTs, the test result is relatively more accurate.

For making the aforesaid features and advantages of the present invention become more apparent and understandable, the following embodiments are taken as examples of the present invention, the detailed description of which and the accompanying drawings are given herein below.

### BRIEF DESCRIPTION OF THE DRAWINGS

FIG. 1 is a top view of a probe card according to an embodiment of the present invention.

FIG. 2A is a side view of a part of the probe card in FIG. 1.

FIG. 2B is a side view of a part of a probe card according to another embodiment of the present invention.

FIG. 2C is a side view of a part of a probe card according to still another embodiment of the present invention.

FIG. 3 is a schematic perspective view of a probe structure in FIG. 1.

FIG. 4 is another schematic perspective view of the probe structure in FIG. 1.

### DETAILED DESCRIPTION OF THE INVENTION

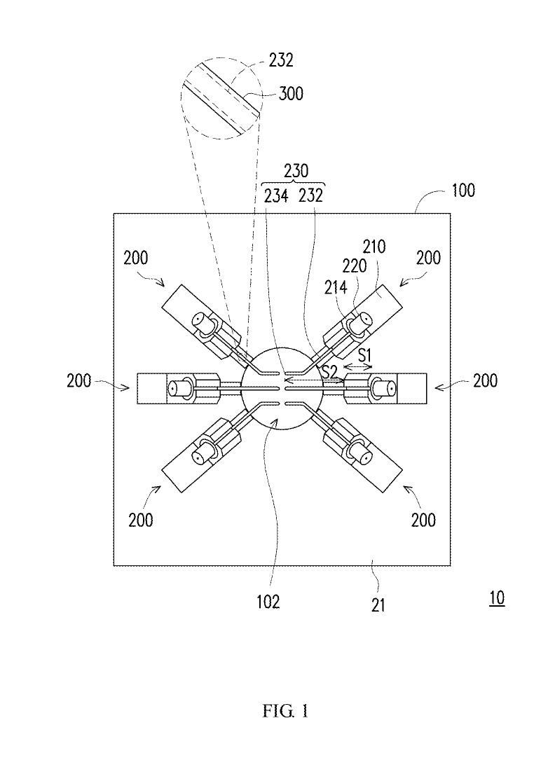

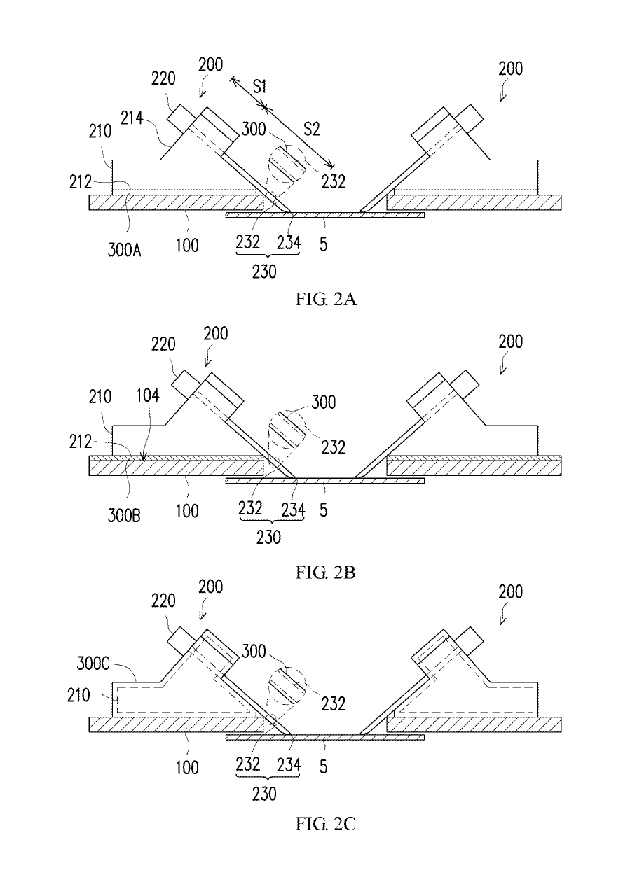

Referring to FIG. 1 and FIG. 2A, the probe card 10 of this embodiment is adapted for testing a plurality of DUTs 5 and transmitting test signals for examining the DUTs to find out whether the function of the DUTs conforms to the expectancy. In FIG. 2A, the substrate 100 and the DUT 5 are depicted in a cross-sectional manner. The DUTs 5 may be integrated circuits or dies on a semi-conductor wafer, for example. The probe card 10 of this embodiment includes a substrate 100, a plurality of probe heads 200, and a wave absorber 300. The substrate 100 has a through hole 102. The plurality of probe heads 200 are disposed on the substrate 100 and arranged around the through hole 102. Each of the probe heads 200 includes a housing 210, a subminiature connector 220 (ex. subminiature type A (SMA) connector), and a probe structure 230. The subminiature connector 220 is disposed on the housing 210. The probe structure 230 is connected to the subminiature connector 220, inserted through the housing 210 and extended to the through hole 102. The wave absorber 300 is disposed between two of the probe structures 230.

Specifically speaking, in this embodiment the substrate 100 may be a printed circuit board, the probe heads 200 may be RF (radio frequency) probes, and the probe heads 200 may be disposed on the substrate 100 and arranged centering around the through hole 102 radially, for example. The amount of the probe heads 200 may be two, four, eight, and so on. The amount of the probe heads 200 is unlimited in the present invention and can be modified by the user according to the usage requirement. The subminiature connector 220 of the probe head 200 is adapted to be connected with a coaxial cable for inputting or outputting signals. The probe structure 230 of the probe head 200 may be a semi-rigid cable, for example. Specifically speaking, the probe structure 230 is a semi-rigid coaxial cable. The probe structure 230 includes a probe main body 232. The probe main body 232 may be a copper pipe, for example, which has a first section 51 and a second section S2. The subminiature connector 220 is connected with the first section 51 of the probe main body 232. The probe main body 232 and the subminiature connector 220 are made integrally or combined through assembly. The housing 210 of the probe head 200 has a bottom portion 212 and a top portion 214. The bottom portion 212 of the housing 210 is disposed on the substrate 100. The probe structure 230 is fixed to the substrate 100 through the housing 210. The subminiature connector 220 is disposed on the top portion 214 of the housing 210. The first section 51 of the probe main body 232 may, but unlimited to, be inserted through the housing 210 inclinedly, for example, so that the subminiature connector 220 is exposed out of the top portion 214 of the housing 210. The second section S2 of the probe main body 232 is exposed out of the housing 210 and extended to the through hole 102, and the terminal end of the second section S2 is inserted through the through hole 102 of the substrate 100 for contacting and probing the DUT 5 positioned under the through hole 102. In this embodiment, the terminal ends of the second sections S2 of the left three probe main bodies 232 are aligned along an imaginary straight line and located on the same imaginary horizontal plane, for example. The terminal ends of the second sections S2 of the right three probe main bodies 232 may be also aligned along an imaginary straight line and located on the same imaginary horizontal plane. Besides, the imaginary straight line, along which the terminal ends of the second sections S2 of the left three probe main bodies 232 are aligned, may be parallel to the other imaginary straight line, along which the terminal ends of the second sections S2 of the right three probe main bodies 232 are aligned. During the test process of the DUTs 5, the tester inputs the test signals to the probe heads 200 through cables connected with the subminiature connectors 220, the test signals are transmitted to the pads or bumps on the DUTs 5 through the probe structures 230, and the probe structures 230 transmit the test results back to the tester for analysis.

In this embodiment, as shown in FIG. 1, the probe card 10 may be divided by the central axis thereof in a way that the middle probe head 200 of the left three and the middle probe head 200 of the right three are paired, the upper probe head 200 of the left three and the upper probe head 200 of the right three are paired, and the lower probe head 200 of the left three and the lower probe head 200 of the right three are paired. The probe heads of the same pair are adapted for testing the same DUT 5, and the probe heads of different pairs are adapted for testing different DUTs 5. For example, the three pairs of probe heads in this embodiment are adapted for testing three different dies on the wafer respectively.

The terminal ends of the second sections S2 of the probe main bodies 232 should be located correspondingly to the pads or bumps on the DUTs 5. The interval between two adjacent subminiature connectors 220 is larger than the interval between the terminal ends of the second sections S2 of two adjacent probe main bodies 232. But the probe main bodies 232 should be as equal as possible in length. Therefore, some probe main bodies 232 have the bent configuration as shown in FIG. 1. A pair of probe heads 200 correspond to a DUT 5 for testing it, but the configuration design of the probe heads 200 is concerned with the test frequency and the experimental simulation. As shown in FIG. 1, the adjacent pairs of probe heads may correspond to the adjacent DUTs 5 or separated DUTs 5 for testing them, wherein the separated DUTs 5 may be separated by a certain amount of DUT 5. As shown in FIG. 1, the condition that the adjacent pairs of probe heads correspond to the DUTs 5 separated by another DUT 5 is taken as an example. In such condition, the upper pair of probe heads 200 correspond to the first DUT 5 for testing it, the middle pair of probe heads 200 correspond to the third DUT 5 for testing it, and the lower pair of probe heads 200 correspond to the fifth DUT 5 for testing it.

In this embodiment, the probe card 10 has a plurality of probe heads 200, so there is liable interference and crosstalk of electromagnetic wave between the probe structures 230 of the probe heads 200. Besides, the metallic surfaces of the DUTs 5 or the ambient electronic components may also cause interference and crosstalk of electromagnetic wave. During the test process of the DUTs 5, the interference and crosstalk of electromagnetic wave may influence the test results, which is undesirable for the user. Therefore, as shown in FIG. 2A, the probe card 10 in this embodiment further has the wave absorber 300, in which the probe main body 232 is cladded. In particularly, the second section S2 of the probe main bodies 232, which is exposed out of the housing 210, is cladded in the wave absorber 300, but the present invention is unlimited thereto. In this way, each wave absorber 300 has at least a part thereof located between the adjacent probe structures 230. The wave absorber 300 may be provided on the probe main body 232 in a coating manner or may be a sleeve sleeved onto the probe main body 232. The material of the wave absorber 300 may, but unlimited to, be rubber, polymer material, the coating material applied to the stealth fighter aircraft, and so on. Specifically speaking, the material of the wave absorber 300 may be aluminum foil coated with ethylene propylene (EPDM), aluminum foil coated with ethylene vinyl acetate (EVA), or ethylene vinyl acetate (EVA). The wave absorber 300 can segregate and restrain the electromagnetic wave emitted from the metallic surfaces of the probe structures 230, the DUTs 5 or the ambient electronic components, thereby reducing the influence of the electromagnetic wave on the test results of the DUTs 5. Besides, the wave absorber 300 may be also disposed between two adjacent subminiature connectors 220 and extended toward the cables, thereby also located between two adjacent cables.

In this embodiment, as shown in FIG. 2A, there may be another wave absorber 300A disposed between the bottom portion 212 of each housing 210 and the substrate 100. In another embodiment not shown in the figures, there may be no such wave absorber 300A, so that the housing 210 is directly disposed on the substrate 100. In another embodiment as shown in FIG. 2B, a surface 104 of the substrate 100, on which the housings 210 are disposed, may be completely covered by a wave absorber 300B which is depicted in a cross-sectional manner in FIG. 2B and located between the housings 210 and the substrate 100, especially between the bottom portions 212 of the housings 210 and the substrate 100. In another embodiment as shown in FIG. 2C, there may be a wave absorber 300C covering the whole housing 210, and the wave absorber 300C may be coated on the housing 210. The wave absorber 300A or the wave absorber 300B may be a plate. For example, the material of the plate is a ceramic substrate including 90 to 99.5 percent of aluminum oxide (AL₂O₃), a ceramic substrate including zirconium dioxide (PSZ), and so on. The material of the wave absorber 300C is the same with the material of the wave absorber 300. Besides, the material of the housing 210 may directly use the material of the wave absorber. That means, the housing 210 is made of the aforesaid material capable of absorbing wave, of which the wave absorber 300A and the wave absorber 300B are made, and the effect of such housing 210 is the same with the effect of the wave absorber 300C. The material of the wave absorber can be chosen according to the frequency of the wave to be absorbed.

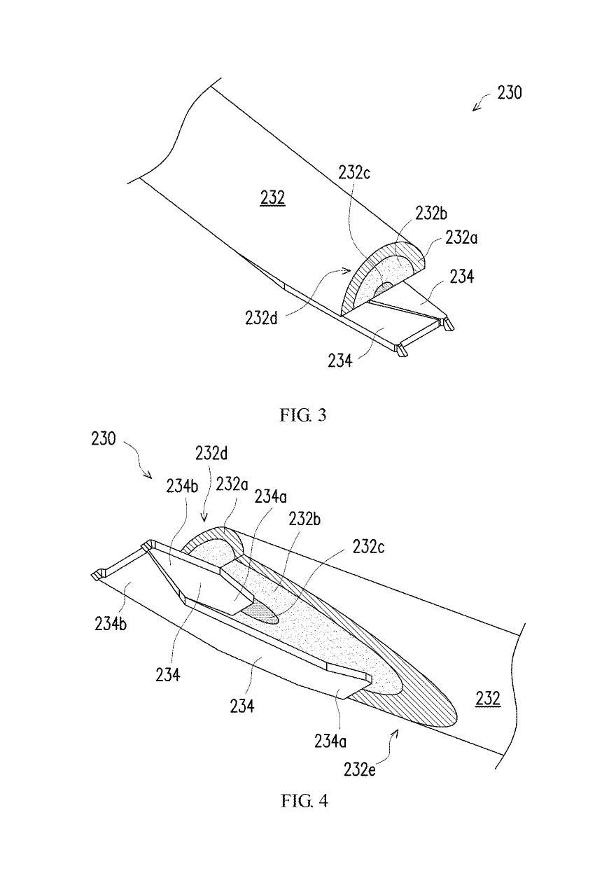

FIG. 3 is a schematic perspective view of the probe structure in FIG. 1. FIG. 4 is another schematic perspective view of the probe structure in FIG. 1. Referring to FIG. 3 and FIG. 4, the probe structure 230 in this embodiment is a coaxial probe structure, for example. The probe main body 232 is shaped as a circular strip including an outer conductor 232a, an insulating layer 232b and an inner conductor 232c, which are arranged coaxially from outside to inside of the probe main body. The outer conductor 232a and the inner conductor 232c are separated from each other by the insulating layer 232b. The probe main body 232 has an end surface 232d and a beveled surface 232e. The end surface 232d is located at an end of the second section S2 of the probe main body 232. The normal direction of the end surface 232d is approximately parallel to the longitudinal direction of the probe main body 232. The outer conductor 232a, the insulating layer 232b and the inner conductor 232c are exposed on the end surface 232d. The beveled surface 232e is extended from an end of the probe main body 232 to another end of the probe main body 232 and inclinedly cuts across the outer conductor 232a, the insulating layer 232b and the inner conductor 232c to be shaped as an elongated ellipse, so that the outer conductor 232a, the insulating layer 232b and the inner conductor 232c are partially exposed on the beveled surface 232e flatly. In other words, the beveled surface 232e includes a cutting section of the outer conductor 232a, a cutting section of the insulating layer 232b and a cutting section of the inner conductor 232c.

In this embodiment, the probe structure 230 further includes a plurality of detectors 234. The detector 234 may, but unlimited to, be made by the MEMS manufacturing process and shaped as a blade or a cantilever beam. The detector 234 has a fixed end 234a and a detecting end 234b. The detecting end 234b inserted through the through hole 102 for detecting the DUT 5 by contacting the pad or bump on the DUT 5. The fixed end 234a may be fixed to the beveled surface 232e of the probe main body 232 by welding, for example. The fixed end 234a of at least one of the detectors 234 is electrically connected to the part of the outer conductor 232a exposed on the beveled surface 232e, and the fixed end 234a of at least one of the detectors 234 is electrically connected to the part of the inner conductor 232c exposed on the beveled surface 232e. For example, the probe structure 230 has a detector 234, the fixed end 234a of which is electrically connected to the part of the outer conductor 232a exposed on the beveled surface 232e and defined for grounding, and another detector 234, the fixed end 234a of which is electrically connected to the part of the inner conductor 232c exposed on the beveled surface 232e and defined for transmitting test signals, and the detectors 234 are not connected with each other. Alternatively, the probe structure 230 may have two detectors 234, the fixed ends 234a of which are electrically connected to the part of the outer conductor 232a exposed on the beveled surface 232e and defined for grounding, and two other detectors 234, the fixed ends 234a of which are electrically connected to the part of the inner conductor 232c exposed on the beveled surface 232e and defined for transmitting test signals. When the outer conductor 232a of the probe main body 232 is defined for grounding, the outer conductor 232a is also effective in shielding the electromagnetic wave emitted from the probe main body 232. The amount of the detector 234 electrically connected to the outer conductor 232a or inner conductor 232c is unlimited in this embodiment. The detector 234 electrically connected to the outer conductor 232a and the detector 234 electrically connected to the inner conductor 232c may be defined for grounding and transmitting test signals respectively or defined for transmitting test signals and grounding respectively.

In conclusion, the probe card of the present invention includes a plurality of probe heads for testing a plurality of DUTs to find out whether the function thereof conforms to the expectancy. In the present invention, not only the outer conductor of the probe main body is used for grounding so as to shield the electromagnetic wave emitted from the probe structure, but the wave absorber covering the probe main body or the housing or disposed between the housing and the substrate is also used for further segregating and restraining the electromagnetic wave emitted from the metallic surfaces of the probe structures, DUTs or the ambient electronic components, thereby reducing the interference and crosstalk between the electromagnetic wave. In this way, when the probe card is applied to test a plurality of DUTs, the electromagnetic wave will not influence the test of the plurality of DUTs, so the test result is relatively more accurate.

Although the present invention is disclosed through the above embodiments, but the disclosure is not intended to limit the scope of the invention. The invention may be varied or modified by anyone skilled in the art, and such variations and modifications are not to be regarded as a departure from the spirit and scope of the invention, so the scope of the invention should be delimited according to the following claims.

What is claimed is:

1. A probe card comprising:
a substrate having a through hole;
a plurality of probe heads disposed on the substrate and arranged around the through hole, each of the probe heads comprising:
a housing;
a subminiature connector disposed on the housing; and
a probe structure connected to the subminiature connector, inserted through the housing and extended to the through hole; and
a wave absorber disposed between two of the probe structures.

2. The probe card as claimed in claim 1, wherein the housing comprises a bottom portion and a top portion opposite to the bottom portion; the subminiature connector is disposed on the top portion of the housing.

3. The probe card as claimed in claim 1, wherein the probe structure comprises a probe main body connected to the subminiature connector; the probe structure and the subminiature connector are made integrally or assembled with each other.

4. The probe card as claimed in claim 3, wherein the probe main body is cladded in the wave absorber.

5. The probe card as claimed in claim 4, wherein the probe main body comprises a first section and a second section; the subminiature connector is connected with the first section; the first section is inserted through the housing; the second section is exposed out of the housing and cladded in the wave absorber.

6. The probe card as claimed in claim 4, wherein the probe structure is a coaxial probe structure; the probe main body comprises an outer conductor, an insulating layer and an inner conductor, which are arranged coaxially from outside to inside of the probe main body.

7. The probe card as claimed in claim 6, wherein the probe main body has an end surface and a beveled surface; the end surface is located at an end of the probe main body; the outer conductor, the insulating layer and the inner conductor are exposed on the end surface; the beveled surface is extended from an end of the probe main body to another end of the probe main body and extended across the outer conductor, the insulating layer and the inner conductor so that the outer conductor, the insulating layer and the inner conductor are partially exposed on the beveled surface; the probe structure further comprises a plurality of detectors; each of the detectors has a fixed end and a detecting end for contacting a device under test positioned under the through hole; the fixed end of at least one of the detectors is electrically connected to a part of the outer conductor exposed on the beveled surface; the fixed end of at least one of the detectors is electrically connected to a part of the inner conductor exposed on the beveled surface.

8. The probe card as claimed in claim 4, wherein the wave absorber is made of one of aluminum foil coated with ethylene propylene and aluminum foil coated with ethylene vinyl acetate.

9. The probe card as claimed in claim 4, wherein a material of the wave absorber comprises ethylene vinyl acetate.

10. The probe card as claimed in claim 1, further comprising:
another wave absorber disposed on a bottom portion of an associated said housing and located between the associated housing and the substrate.

11. The probe card as claimed in claim 10, wherein said another wave absorber is a plate which is one of a ceramic substrate comprising 90 to 99.5 percent of aluminum oxide and a ceramic substrate comprising zirconium dioxide.

12. The probe card as claimed in claim 1, further comprising:
another wave absorber, the substrate having a surface where the housing is disposed, the surface of the substrate being completely covered by said another wave absorber which is located between the housings and the substrate.

13. The probe card as claimed in claim 12, wherein said another wave absorber is a plate which is one of a ceramic substrate comprising 90 to 99.5 percent of aluminum oxide and a ceramic substrate comprising zirconium dioxide.

14. The probe card as claimed in claim 1, further comprising:
another wave absorber completely covering an associated said housing.

15. The probe card as claimed in claim 14, wherein a material of said another wave absorber is identical with a material of the wave absorber.

16. The probe card as claimed in claim 1, wherein a material of the housing comprises a material of absorbing wave.

17. The probe card as claimed in claim 1, wherein a material of the housing comprises one of ceramic comprising 90 to 99.5 percent of aluminum oxide and ceramic comprising zirconium dioxide.
